(19) United States
(12) Patent Application Publication
(10) Pub. No.: US 2017/0297919 A1
(43) Pub. Date: Oct. 19, 2017

(54) GETTER COMPOSITION COMPRISING MAGNESIUM OXIDE PARTICLES DOPED WITH ALKALI METAL (As Amended)

(71) Applicant: LG CHEM, LTD., Seoul (KR)

(72) Inventors: Won Bae BYUN, Daejeon (KR); Donghwan KIM, Daejeon (KR); Su Hee LEE, Daejeon (KR); Cheol-Hee PARK, Daejeon (KR)

(21) Appl. No.: 15/510,200

(22) PCT Filed: Dec. 23, 2015
(86) PCT No.: PCT/KR2015/014197

§ 371 Date: Mar. 9, 2017

(30) Foreign Application Priority Data
Jan. 2, 2015 (KR) 10-2015-0000060
Dec. 22, 2015 (KR) 10-2015-0184054

(51) Int. Cl. C01F 5/22; H01L 23/31; H01L 23/26; H01L 23/00

(52) U.S. Cl. CPC C01F 5/22; H01L 23/564; H01L 23/31; H01L 23/26; C01P 2004/64

(57) ABSTRACT

The present invention relates to a getter composition comprising magnesium oxide particle doped with alkali metal, a getter layer comprising the same, and an organic electronic device comprising the getter layer. The getter composition comprising magnesium oxide particle doped with alkali metal according to the present invention has remarkably improved hygroscopicity simultaneously with maintaining transparency of the previously used magnesium oxide particles, and thus, is used in a getter layer comprising the same and an organic electronic device comprising the getter layer, thereby effectively protecting water sensitive devices.

### CROSS-REFERENCE TO RELATED APPLICATION(S)

This application claims the benefit of Korean Patent Application No. 10-2015-0000060 filed on Jan. 2, 2015 and Korean Patent Application No. 10-2015-0184054 filed on Dec. 22, 2015 with the Korean Intellectual Property Office, the disclosures of which are herein incorporated by reference in their entirety.

### TECHNICAL FIELD

The present invention relates to a getter composition comprising magnesium oxide particle doped with alkali metal, a getter layer comprising the getter composition, and an organic electronic device comprising the getter layer.

### BACKGROUND OF ART

An organic electronic device (OED) means a device comprising an organic material layer that generates alternating current of electric charge, and, for example, it may include a photovoltaic device, a rectifier, a transmitter and an organic light emitting diode (OLED), and so on.

Among the organic electronic devices, an organic light emitting diode (OLED) has smaller power consumption and faster response speed, compared to the existing light source, and is advantageous for thinning of a display device or lighting. Further, an OLED has excellent space utilization, and thus, is expected to be applied in a variety of fields including various portable devices, monitors, notebooks, and TV.

Since a light emitting element, which is an important element in an organic electronic device, is oxidized if it contacts with moisture, sealing of the organic electronic device is importantly considered in the preparation process so as to improve durability and life expectancy of the organic electronic device. Thus, in order to effectively block the contact of a light emitting element with moisture, moisture is blocked in two points of view, one is to block moisture by physical sealing, and the other is to seal material capable of absorbing moisture, i.e., a hygroscopic agent, together inside the organic electronic device.

The physical sealing method connects the front substrate and the rear substrate with a highly adhesive sealant so that the light emitting element may not be exposed outside. However, since moisture may penetrate by an external environment where the organic electronic device is used, a hygroscopic agent may be sealed together with a light emitting element to prevent the light emitting element from contacting with moisture. As such, a composition comprising a hygroscopic agent is referred to as a getter composition.

In general, an organic electronic device is prepared by forming a light emitting device on the rear substrate, forming a getter layer with a getter composition on the front side, and sealing the rear substrate and the front substrate. As the getter layer, material that has high moisture absorption amount, and does not easily discharge absorbed moisture should be used. Further, the getter layer should have transmittance so as to transmit light emitted in a light emitting element.

Conventionally, a metal can or glass was processed in the form of a cap with a groove, and a desiccant for moisture absorption was loaded in the form of powder on the groove, or was prepared in the form of a film and adhered using a double-side tape. However, a method of loading a desiccant cannot be used for front side light emission because the process is complicated, thus increasing material and process costs, the whole thickness of the substrate becomes thick, and a substrate used for sealing is not transparent.

Further, Korean Patent Publication No. 10-2007-0072400 describes a method of including a moisture adsorbent in an epoxy sealant to chemically adsorb moisture entering into an organic light emitting device, thus delaying the penetration speed of moisture into the organic light emitting device. However, the moisture adsorbent may react with moisture to expand the volume, thereby physically damaging the organic light emitting device, and in case metal oxide is used as the moisture adsorbent, it may react with moisture to form strongly basic material, thus chemically damaging a protection layer and a negative electrode layer, and so on.

Further, the previously used desiccant or moisture adsorbent has a large particle size and has difficulty in realizing a transparent getter layer, and thus, it cannot be applied for a top-emission type organic electronic device that can maximize the light emission efficiency, for example, an OLED device, and it does not have good moisture absorption capability, thus lowering durability and life expectancy of the organic electronic device.

Thus, the present inventors, during studies on a getter composition having excellent hygroscopicity and transparency, confirmed that magnesium oxide particle doped with alkali metal as explained below have remarkably improved hygroscopicity compared to the conventionally used magnesium oxide particles, and completed the present invention.

### DETAILED DESCRIPTION OF THE INVENTION

### Technical Problem

It is an object of the present invention to provide a method for preparing a getter layer that not only has excellent hygroscopicity and transparency but also can be uniformly formed on a substrate.

It is another object of the present invention to provide an organic electronic device comprising a getter layer prepared by the above preparation method.

### Technical Solution

The present invention provides a getter composition comprising magnesium oxide particles doped with alkali metal.

As used herein, the term ‘getter composition’ means a composition comprising material capable of absorbing moisture, and it means material that absorbs moisture penetrating inside a device comprising a water sensitive device such as an organic electronic device. Particularly, since, among organic electronic devices, a light emitting device is small-sized and requires a getter layer capable of transmitting light generated in the light emitting device, a getter layer comprising a getter composition with transparency and hygroscopicity as described above is required.

Conventionally, a getter composition comprising magnesium oxide particles has been used. Magnesium oxide can be prepared as particles with a diameter of 100 nm or less, and in this case, it has not only transparency but also hygroscopicity of magnesium oxide itself, and thus, can be usefully used in a getter layer. However, since magnesium oxide particles absorb, based on magnesium oxide, about 10 wt % of moisture under conditions of 60° C. and 40 RH %, material with further improved moisture uptake is required.

Thus, in the present invention, magnesium oxide particles doped with alkali metal is used instead of conventionally used magnesium oxide particles, and it was confirmed that, in this case, moisture uptake is remarkably increased.

The magnesium oxide particles doped with alkali metal means that alkali metal is added in the crystal structure of magnesium oxide particles. Here, the added amount of the alkali metal can be calculated by the following Equation:

Doped amount of alkali atom (wt %)=(mass of alkali atom (g))/(MgO mass (g)+mass of alkali atom (g))×100

Although not theoretically limited, if alkali metal is added in the crystal structure of magnesium oxide particles, it substitutes and penetrates into lattice atoms to generate surface defect, and thus, surface area becomes wider, and consequently, moisture uptake may be remarkably increased.

It is preferable that the alkali metal is Na, Li or K. The doped amount of the alkali metal is 0.1 to 5 wt %. A method of doping magnesium oxide particles with the alkali metal will be explained later.

Further, it is preferable that the diameters of the magnesium oxide particles are 5 to 50 nm.

Further, the present invention provides a method for preparing the magnesium oxide doped with the alkali metal, comprising the steps of:

1) mixing magnesium oxide and alkali metal salt to prepare a mixture;

2) drying the mixture; and

3) heat-treating the dried mixture.

The step 1 is a step of mixing magnesium oxide with alkali metal salt, which is a precursor of alkali metal to be doped with magnesium oxide.

The magnesium oxide may be commercially purchased, or prepared by the method of Comparative Example as described below. Further, as the alkali metal salt, NaN₃, NaCO₃, NaOH, NaCl, NaNO₃, Na₂SO₄, CH₃COONa, LiN₃, Li₂CO₃, LiOH, LiCl, LiNO₃, Li₂SO₄, CH₃COOLi, KN₃, K₂CO₃, KOH, KCl, KNO₃, K₂SO₄, or CH₃COOK may be used. The doped amount of alkali metal may be controlled by controlling the weight ratio of the magnesium oxide and alkali metal salt, and it is preferable that, based on magnesium oxide, 0.1 to 5 wt % of alkali metal salt is mixed.

The solvent of the mixture is not specifically limited as long as it can dissolve both magnesium oxide and alkali metal salt, and, for example, water, ethyleneglycol, methanol, or ethanol may be used.

The step 2 is a step of removing the solvent in the reaction product of the mixture of step 1.

If the mixture of step 1 reacts, Mg(OH)₂ is produced, and the solvent of the mixture may be dried to obtain a product in the form of powder.

It is preferable that the drying is carried out such that the solvent may be sufficiently removed, and, for example, it may be carried out at a temperature of 100 to 200° C., or by vacuum drying or freeze drying.

The step 3 is a step of heat-treating the powder obtained in step 2 to prepare magnesium oxide particles doped with alkali metal.

Magnesium oxide is formed in the heat-treatment process, wherein alkali metal existing together is involved in the formation of magnesium oxide, and the alkali metal is doped in the crystal structure of magnesium oxide.

It is preferable that the heat-treatment is carried out at a temperature of 300 to 800° C. If the temperature is less than 300° C., the formation of magnesium oxide may be insignificant, and if it exceeds 800° C., the particle size may become large.

It is preferable that the heat-treatment is sufficiently carried out for the time during which magnesium oxide is formed, and, for example, it is preferable that heat-treatment is carried out for 30 minutes to 2 hours.

It is preferable that the heat-treatment is carried out under inert gas, and as the inert gas, N₂ or Ar may be used.

Meanwhile, according to the example of the present invention, there is no substantial difference between the crystal structure of magnesium oxide before doped with alkali metal and the crystal structure of magnesium oxide doped with alkali metal. It means that, even if alkali metal is doped in magnesium oxide, it does not have a large influence on the crystal structure of magnesium oxide, and thus, the property of magnesium oxide such as transparency may be maintained intact.

Further, the present invention provides a getter layer comprising the above getter composition. The getter layer comprises the magnesium oxide doped with alkali metal as explained above, and due to the transparency and hygroscopicity, it may be usefully used as a getter layer of an organic electronic device.

The getter layer may further comprise a binder, and so on, so as to maintain the shape of the getter layer and increase adhesion with a substrate that contacts with the getter layer, besides the getter composition. As the examples of the binder, polyvinylpyrrolidone, citric acid, cellulose, acrylate polymer, polyurethane, polyester, and so on, may be mentioned.

A method of using the getter composition as a getter layer of an organic electronic device is not specifically limited, and, for example, a getter layer may be formed by mixing the getter composition with an adsorbent solution and then applying or coating it on the front side of a substrate. A method of coating is not specifically limited, and for example, dip-coating, spin-coating, printing-coating and spray-coating, and so on, may be used.

Further, it is preferable that the thickness of the getter layer is 1 to 50 um. If the thickness is less than 1 um, moisture absorption by the getter layer may be small, and if it exceeds 50 um, transparency may decrease due to the thickness of the getter layer too thick or it may not be appropriate for the miniaturization of an organic electronic device.

One example of the method of using the getter layer in an organic electronic device is schematically shown in FIG. 1.

As shown in FIG. 1, an organic electroluminescence part (12) is formed on the rear substrate (10), and a getter layer (13) is formed on the front substrate (11), and then, the rear substrate (10) and the front substrate (11) are sealed with a sealant (14) so that the organic electroluminescence part (12) and the getter layer (13) face each other.

The organic electroluminescence part (12) may be formed by deposition, and it may consist of a first electrode, an organic film, and a second electrode, in this order. Further, the organic film comprises a hole injection layer, a hole transport layer, a light emitting layer, an electron injection layer, and/or an electron transport layer.

As the front substrate (11), a glass substrate or transparent plastic substrate may be used, and in case it is formed of a plastic substrate, a protection film for protecting from moisture may be further formed on the inner side of the plastic substrate.

Further, it is preferable that the internal space divided by the front substrate (11) and the rear substrate (10) is maintained as a vacuum state or filled with inert gas.

Further, the present invention provides an organic electronic device comprising the getter layer. The examples of the organic electronic device may include a photovoltaic device, a rectifier, a transmitter and an organic light emitting diode (OLED), and so on.

### Advantageous Effects

The getter composition comprising magnesium oxide particle doped with alkali metal according to the present invention has remarkably improved hygroscopicity simultaneously with maintaining transparency of the previously used magnesium oxide particles, and thus, is used in a getter layer comprising the same and an organic electronic device comprising the getter layer, thereby effectively protecting water sensitive devices.

### BRIEF DESCRIPTION OF THE DRAWINGS

FIG. 1 schematically shows the structure of an organic electronic device for which the getter layer of the present invention is applied.

FIG. 2 shows the XRD analysis result of MgO prepared in Comparative Example.

FIG. 3 shows the XRD analysis result of K-doped MgO prepared in Example 1 of the present invention.

FIG. 4 shows the XRD analysis result of Li-doped MgO prepared in Example 2 of the present invention.

FIG. 5 shows the hygroscopicity test results of MgO, K-doped MgO and Li-doped MgO prepared in Comparative Example, Examples 1 and 2 of the present invention.

FIG. 6 shows the hygroscopicity test results of Li-doped MgO and Na-doped MgO prepared in Examples 3 to 5 of the present invention.

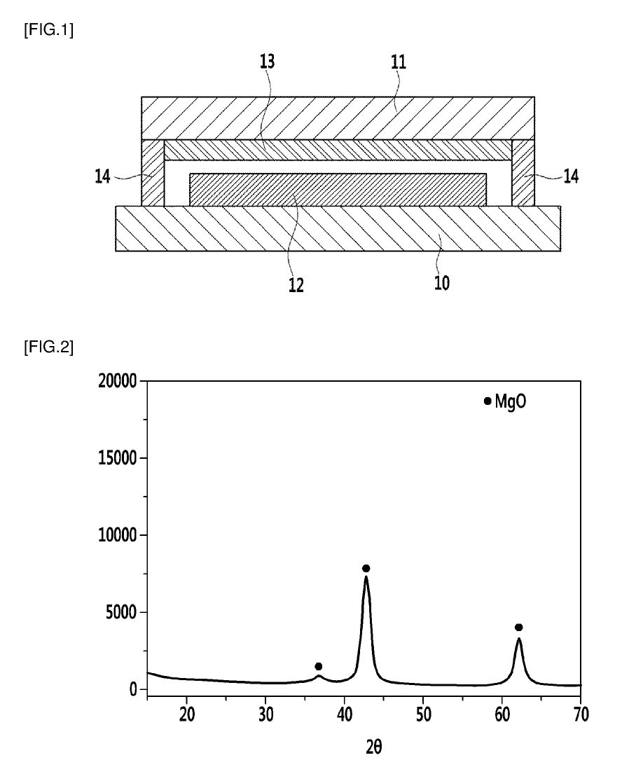

### DETAILED DESCRIPTION OF THE EMBODIMENTS

Hereinafter, preferable examples are presented for better understanding of the present invention. However, these examples are provided only to more easily understand the present invention, and the scope of the present invention is not limited thereto.

### Comparative Example: Preparation of MgO Powder

51.3 g of Mg(NO₃)₂-6H₂O was dissolved in 75 mL of distilled water, and 25 mL of ethylene glycol was added thereto. 16 g of NaOH was dissolved in 30 mL of water, which was added to the above solution to precipitate Mg(OH)₂. The precipitate was washed with distilled water and ethanol sequentially, and sufficiently dried at 150° C. to obtain powder. The obtained powder was heat-treated under nitrogen atmosphere at 400° C. for 1 hour to obtain MgO powder.

### Example 1: Preparation of K-Doped MgO Powder

3 g of MgO prepared in Comparative Example was introduced into 20 mL of distilled water, a solution of 0.054 g of K₂CO₃ dissolved in 20 mL of distilled water was introduced therein, and the mixed solution was stirred. The solution was sufficiently dried at 150° C. to obtain powder. The obtained powder was heat-treated under nitrogen atmosphere at 400° C. for 1 hour to obtain K-doped MgO powder. The doped amount of K was 1 wt %, which was confirmed by ICP (Inductively Coupled Plasma).

### Example 2: Preparation of Li-Doped MgO Powder

Li-doped MgO powder was obtained by the same method as Example 1, except using 0.161 g of Li₂CO₃ instead of K₂CO₃. The doped amount of Li was 1 wt %, which was confirmed by ICP.

### Example 3: Preparation of Li-Doped MgO Powder

Li-doped MgO powder was obtained by the same method as Example 1, except using 0.183 g of LiOH—H₂O instead of K₂CO₃. The doped amount of Li was 1 wt %, which w as confirmed by ICP.

### Example 4: Preparation of Li-Doped MgO Powder

Li-doped MgO powder was obtained by the same method as Example 1, except using 0.301 g of LiNO₃ instead of K₂CO₃. The doped amount of Li was 1 wt %, which was confirmed by ICP.

### Example 5: Preparation of Na-Doped MgO Powder

Na-doped MgO powder was obtained by the same method as Example 1, except using 0.086 g of NaN₃ instead of K₂CO₃. The doped amount of Na was 1 wt %, which was confirmed by ICP.

### Experimental Example 1: XRD Result

In order to confirm MgO crystallinities of MgO powder and K-doped MgO powder respectively prepared in Comparative Example and Examples 1 and 2, XRD analysis was conducted, and the results are shown in FIGS. 2 to 4.

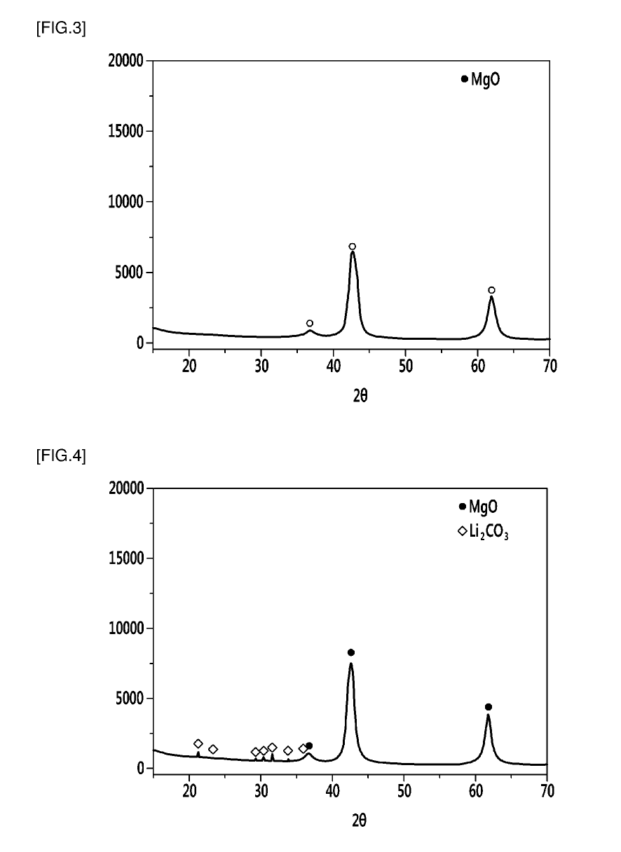

As shown in FIGS. 2 and 3, it was confirmed that the XRS pattern of MgO of Comparative Example in FIG. 2 almost correspond with the XRD pattern of K-doped MgO of Example 1 in FIG. 3. It was also confirmed that the XRD pattern of Li-doped MgO of Example 2 in FIG. 4 almost correspond with the XRD pattern of MgO of Comparative Example in FIG. 2.

From the foregoing results, it was confirmed that even in case MgO is doped with alkali metal, the crystallinity of MgO is maintained intact.

### Experimental Example 2: Hygroscopicity Test

0.3 to 0.5 g of the powder prepared in Comparative Example and Examples 1 to 5 were respectively put in a vial, and it was put in a thermo-hygrostat (60° C., 40 RH %), and then, mass was measured at fixed times, thus measuring moisture absorption amount.

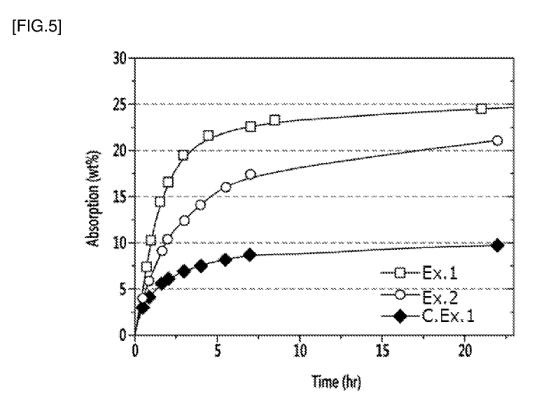

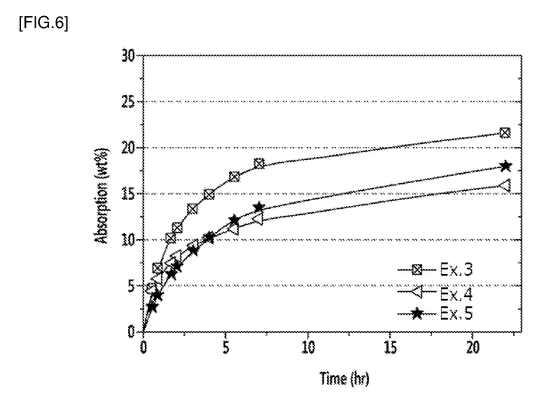

The test results are shown in FIG. 5 and FIG. 6. As shown in FIG. 5 and FIG. 6, hygroscopicity remarkably increased compared to MgO of Comparative Example, and particularly, in the case of Example 1, moisture absorption amount remarkably increased by about 2.5 times.

### DESCRIPTION OF SYMBOLS

10: rear substrate
11: front substrate
12: organic electroluminescence part
13: getter layer
14: sealant

1. A getter composition comprising magnesium oxide particles doped with alkali metal.

2. The getter composition according to claim 1, wherein the alkali metal is Na, Li, or K.

3. The getter composition according to claim 1, wherein the magnesium oxide particles have a diameter of 5 to 50 nm.

4. The getter composition according to claim 1, wherein the magnesium oxide particles doped with alkali metal are prepared by a method comprising the step of:
1) mixing magnesium oxide and alkali metal salt to prepare a mixture;
2) drying the mixture; and
3) heat-treating the dried mixture.

5. The getter composition according to claim 4, wherein the alkali metal salt is NaN₃, NaCO₃, NaOH, NaCl, NaNO₃, Na₂SO₄, CH₃COONa, LiN₃, Li₂CO₃, LiOH, LiCl, LiNO₃, Li₂SO₄, CH₃COOLi, KN₃, K₂CO₃, KOH, KCl, KNO₃, K₂SO₄, or CH₃COOK.

6. The getter composition according to claim 4, wherein, based on the magnesium oxide, 0.1 to 5 wt % of alkali metal salt is mixed.

7. The getter composition according to claim 4, wherein the solvent of the mixture is water, etyleneglycol, methanol, or ethanol.

8. The getter composition according to claim 4, wherein the drying is carried out at a temperature of 100 to 200° C., or by vacuum drying or freeze drying.

9. The getter composition according to claim 4, wherein the heat-treatment is carried out at a temperature of 300 to 800° C.

10. The getter composition according to claim 4, wherein the heat-treatment is carried out for 30 minutes to 2 hours.

11. A getter layer comprising the getter composition according to claim 1.

12. The getter layer according to claim 11, wherein the thickness of the getter layer is 1 to 50 um.

13. An organic electronic device comprising the getter layer of claim 11.
